(19) United States
(12) Patent Application Publication
(10) Pub. No.: US 2007/0182425 A1
(43) Pub. Date: Aug. 9, 2007

(54) Safety mechanism for holiday detector

(76) Inventors: Mark J. Byerley, Chino, CA (US); Peter L. Harkins, Glendale, CA (US); Roman Chak, North Hollywood, CA (US)

Correspondence Address: David A. Schnider, 801 South Figueroa St. 18th Floor, Los Angeles, CA, 90017, US

(21) Appl. No.: 11/346,810

(22) Filed: Feb. 3, 2006

(51) Int. Cl. G01R 27/08; G01M 19/00; H02H 7/00

(52) U.S. Cl. 324/700; 73/865.8; 361/1

(57) ABSTRACT

The present invention relates to a safety mechanism for holiday detectors. When a user properly holds a holiday detector, a safety button is engaged which allows the holiday detector to be turned on. If the safety button is not engaged, the holiday detector cannot be turned on. The holiday detector then remains on only as long as the safety button is engaged. In other embodiments of the invention, a lanyard connects a safety switch on the holiday detector to the user. If the user were to drop the holiday detector, the lanyard would flip the safety switch thus shutting off power to the holiday detector.

### BACKGROUND OF THE INVENTION

1. Field of the Invention

The present invention relates generally to safety mechanisms for holiday detectors. Specifically, this invention teaches various safety mechanisms for shutting off the power to a holiday detector.

2. Background Information

Millions of miles of pipeline are buried throughout the world. These pipelines transport various hazardous gases and liquids, oftentimes at high pressure. The main cause of pipeline failure is from corrosion of the pipe material. In order to prevent corrosion, pipelines are generally coated with an insulating material securely bonded to the pipe. The safe transport of materials is thus dependent on the integrity of the pipeline which must be checked on a regular basis.

Since the early to mid 1900's, holiday detectors have been used to verify the integrity of pipelines. Holiday detectors allow for the electrical inspection of the continuity of a pipes protective coating. The holiday detector typically detects voids, cracks, foreign inclusions, or contaminates (“holidays”) in the coating by checking the resistivity of non-conducting coatings on metallic pipes through the application of a voltage to the non-conductive protective coating. This is done by attaching a ground connection to the conductive substrate and passing an energized electrode over the non-conductive coating. When a holiday in the coating comes in contact with the energized electrode, the energy passes through the holiday to the substrate and returns to the ground. This completes a circuit within the holiday detector. The holiday detector then typically gives a visual and/or audible alarm notifying the user of the holiday in the pipeline.

Surprisingly, although the holiday detector depends on the continual emission of electrical currents, there are currently no mechanisms which regulate the automatic shut-off of a holiday detector. Accordingly, the present invention seeks to employ various electrical shut-off mechanisms thereby by protecting the user of a holiday detector from possible electric shock.

The claimed invention provides this protection by maintaining power only when the holiday detector is held properly by a user. Whenever the holiday detector is not properly held, the power automatically shuts off. In addition, as an added safety feature, the holiday detector can only be powered-up when the holiday detector is properly held. From the preceding descriptions, it is apparent that the devices currently being used have significant disadvantages and/or limitations regarding safety. Thus, important aspects of the technology used in the field of invention remain amenable to useful refinement.

### SUMMARY OF THE INVENTION

The present invention relates to an apparatus that satisfies the need for a safety electric shut-off mechanism for holiday detectors. In one preferred embodiment, a safety mechanism on a holiday detector having features of the present invention comprises an appendage on a holiday detector which engages a safety button. When a user properly holds a holiday detector, the appendage engages the safety button which allows the holiday detector to be turned on. If the safety button is not engaged, the holiday detector cannot be turned on. The holiday detector then remains on until the appendage no longer engages the safety button.

In other embodiments of the invention, the user directly engages a safety button when the holiday detector is properly held. Like the previous embodiment, the holiday detector can only be turned on when the user engages the safety button, and only remains on, so long as the safety button is engaged.

In another embodiment of the invention, a switch is used to automatically shut-off power when a holiday detector separates from the user. For example, if the user were to drop the holiday detector, this embodiment would provide for an automatic shutoff. In this embodiment, a lanyard connects the user to an automatic shut-off switch. If the holiday detector separates from the user, the lanyard activates the shut-off switch.

All of the foregoing operational principles and advantages of the present invention will be more fully appreciated upon consideration of the following detailed description with reference to the drawings.

### BRIEF DESCRIPTION OF THE DRAWINGS

The features and advantages of this invention are better understood with regard to the following drawings, description, and claims. The drawings consist of the following:

FIG. 1 is an elevation view of the side of an apparatus embodying features of this invention.

FIG. 2 is an exploded view of the side of the handle, connector, and appendage of an apparatus embodying features of this invention.

FIG. 3 is a exploded view of the handle, connector, and appendage of an apparatus embodying features of this invention.

FIG. 4 is a exploded view of the handle, connector, and appendage of an apparatus embodying features of this invention.

FIG. 5 is a bottom plan view of the handle, connector, and safety button of an apparatus embodying features of this invention.

FIG. 6 is a perspective view of the handle, connector, and safety button of an apparatus embodying features of this invention.

FIG. 7 is a schematic diagram of the power and safety circuit for an apparatus embodying features of this invention.

FIG. 8 is an elevation view of the side of an apparatus embodying features of another embodiment of this invention.

FIG. 9 is an elevation view of the side of an apparatus embodying features of another embodiment of this invention.

FIG. 10(a) is an elevation view of the side of an apparatus embodying features of another embodiment of this invention.

FIG. 10(b) is an elevation view of the side of an apparatus embodying features of another embodiment of this invention.

FIG. 10(c) is a perspective view of an apparatus embodying features of another embodiment of this invention.

FIG. 11(a) is a perspective view of an apparatus embodying features of another embodiment of this invention.

FIG. 11(b) is an perspective view of the lanyard and safety switch of an apparatus embodying features of this invention.

FIG. 12 is an elevation view of the side the lanyard, lanyard connector, safety switch, and switch cover of an apparatus embodying features of this invention.

FIG. 13 is a perspective view of the lanyard, lanyard connector, safety switch, and switch cover of an apparatus embodying features of this invention.

FIG. 14 is an elevation view of the side of the lanyard connector, safety switch, and switch cover of an apparatus embodying features of this invention.

FIG. 15 is top plan view of the lanyard connector, safety switch, and switch cover of an apparatus embodying features of this invention.

FIG. 16 is an elevation view of the side of the lanyard connector, safety switch, and switch cover of an apparatus embodying features of this invention.

FIG. 17 is top plan view of the lanyard connector, safety switch, and switch cover of an apparatus embodying features of this invention.

FIG. 18 is an elevation view of the side of the lanyard connector, safety switch, and switch cover of an apparatus embodying features of this invention.

FIG. 19 is top plan view of the lanyard connector, safety switch, and switch cover of an apparatus embodying features of this invention.

FIG. 20 is a schematic diagram of the power and safety circuit for an apparatus embodying features of this invention.

### DETAILED DESCRIPTION OF THE INVENTION

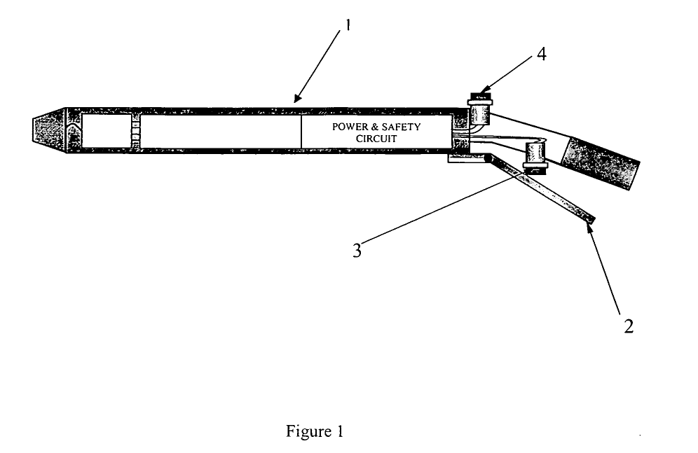

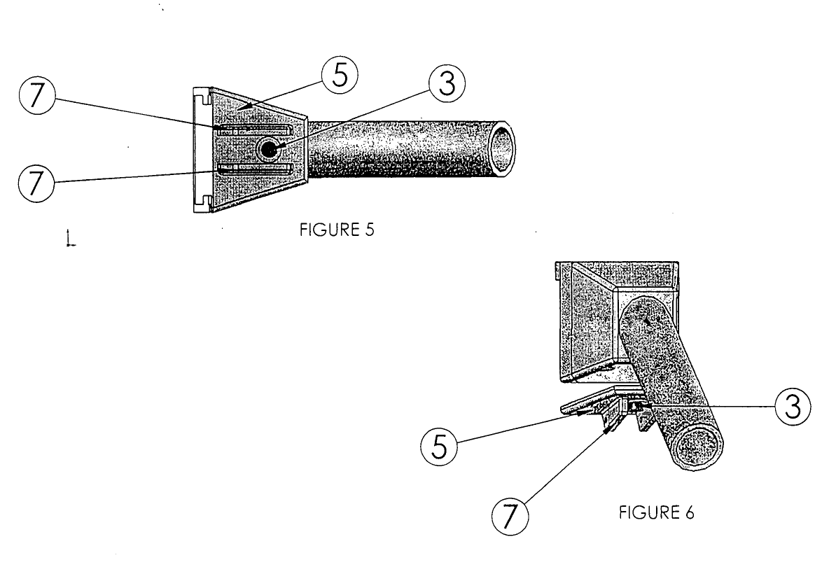

FIGS. 1-7 disclose the first preferred embodiment of a holiday detector 1 with a safety shut-off mechanism. When the user holds the holiday detector 1, a force is applied to the appendage 2 connected to the holiday detector 1. The appendage 2 then engages a safety button 3. The safety button 3 when engaged removes an otherwise applied low potential voltage to a relay wired in a self-latching configuration. As long as the force on the appendage 2 causes the safety button 3 to be engaged, then the holiday detector 1 can be powered on by applying a force to the power button 4. When the power button 4 is pressed, it applies 5 volts to the self-latching relay, which in turn provides 5 volts to enable voltage to power the MOSFET transistors, and thus power the holiday detector 1.

Once powered on, the holiday detector 1 will remain on until the appendage 2 is released. When the appendage 2 of the holiday detector 1 is released, the safety button 3 is disengaged thereby applying a low potential voltage to the self-latching relay, which then disengages the power through the MOSFET transistors, and the holiday detector 1 shuts down.

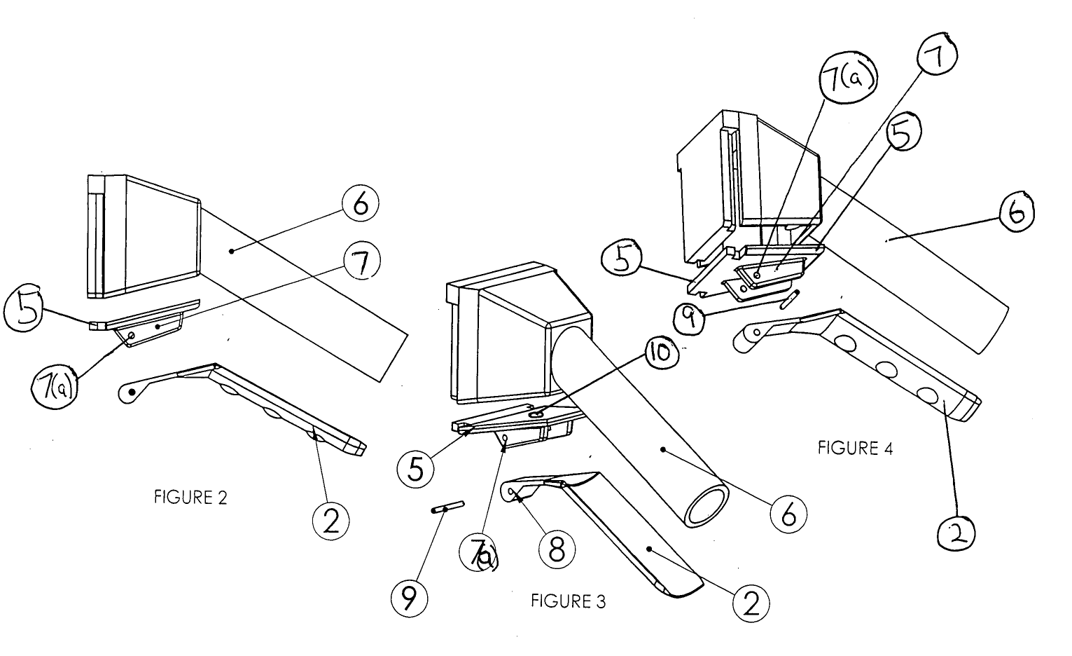

As demonstrated in FIGS. 2-4, the appendage 2 is connected to the handle 6 of a holiday detector 1 by way of a connector 5. The connector 5 has two flanges 7 which protrude from the connector 5 to which the appendage 2 attaches. Each flange 7 has an aperture 7(a) through which the appendage 2 connects to the flange 7. The appendage 2 also has an aperture 8 through which a bolt 9, or other connecting device, passes through one flange 7, then through the appendage 2, to the other flange 7. Finally, as demonstrated in FIGS. 3, 5, and 6 the connector 5, has an aperture 10 through which the safety button 3 protrudes.

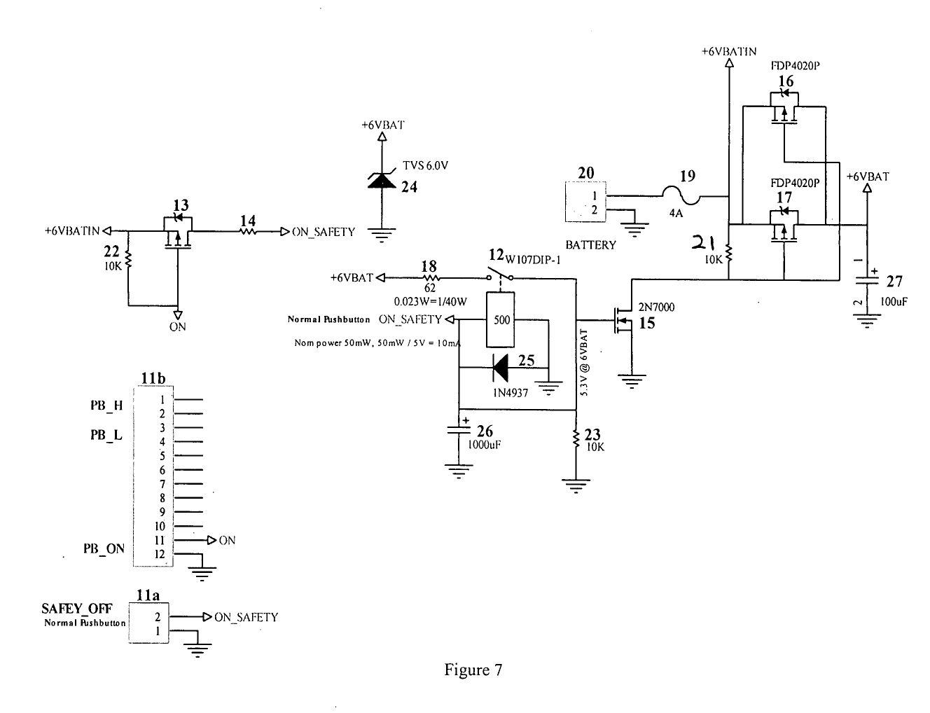

FIG. 7 shows the power & safety circuit diagram for the claimed invention. In the circuit in FIG. 7, JP4 jumper cable 11(a) is connected to the safety button 3. As long as the appendage 2 is not engaged, the safety button 3 will be released, providing a short circuit pass between pins 1 and 2 of JP4 jumper cable 11. Since pin 2 of JP4 jumper cable 11 is connected to one side of K6 relay 12 (in FIG. 2 shown as ON_SAFETY connection node) and pin 1 of JP4 jumper cable 11 is connected to the ground, both sides of K6 relay 12 are effectively shorted down to ground when appendage 2 does not engage the safety button 3. While both sides of K6 relay 12 are connected to ground the coil has no power and K6 relay 12 stays open. The relay will not engage even if power is applied to the coil through Q21 transistor 13 and R59 resistor 14. As a result the unit will stay powered down even if the user applies pressure to the power button 4, so long as the appendage 2 is not engaged.

In the circuit, R59 resistor 14 is the current limiting resistor used to prevent an over-current condition when Q21 transistor 13 is active and conducting current. The gate of Q21 transistor 13 is connected to the power button 4 through JP2 jumper cable 11(b). When the power button 4 is pressed in, the gate of Q21 transistor 13 is pulled to a low potential and Q21 transistor 13 gets activated providing power for K6 relay 12.

Once the appendage 2 is pressed and the safety button 3 engaged, the short circuit link through JP4 jumper cable 11(a) to the ground is removed and the unit is ready to power up. K6 Relay 12 is wired in the self-latching configuration. Once the battery voltage is applied to the ON_SAFETY side of K6 relay 12, K6 will stay engaged even after the power coming from Q21 transistor 13 is removed. As can be seen from FIG. 7, the 6V battery voltage 20 is routed through pins 7 and 1 back to pin 2 of the relay's coil which allows the relay to stay powered permanently. Output of the relay is connected to the Q17 inverter 15. Since Q18 transistor 16 and Q19 transistor 17 are P-Channel MOSFETs, they will require a negative voltage between gate and source to turn on, or V_{G}<V_{S}−V_{TH}, where V_{TH} is the threshold voltage of FDP4020 MOSFET. When K6 relay 12 is engaged Q17 inverter 15 is turned on by the positive voltage coming from +6VBATIN 20 through R56 resistor 18. In turn, Q17 inverter 15 pulls both gates of Q18 transistor 16 and Q19 transistor 17 to a low potential well below V_{TH} placing both MOSFETs in the saturation, or switch, region. As a result current starts flowing through Q18 transistor 16 and Q19 transistor 17 giving the holiday detector 1 power.

A 4A fuse 19 connected to the battery connector protects the circuitry from overload currents. R60 resistor 21 and R69 resistor 22 are pull-up resistors. R61 resistor 23 is a pull down resistor to keep Q17 transistor 15 off when no voltage is applied to the gate of the transistor. D27 transient voltage suppressor 24 protects Q17 transistor 15, Q18 transistor 16, and Q19 transistor 17 from transient high voltage spikes. D17 Diode 25 is a kickback voltage protection diode. C31 Capacitor 26 is used to filter out noise spikes that could fault-trigger K6 relay 12. C33 capacitor 27 is an output voltage filtering capacitor.

To power down the unit a user can release the appendage. When the appendage is released, a short circuit will appear between pins 1 and 2 of JP4 jumper cable 11a. As a result K6 relay 6 will lose its power and the holiday detector 1 will shut down.

In sum, this preferred embodiment is comprised of a holiday detector 1, a power button 4, an appendage 2 coupled to the holiday detector 1, and a safety button 3 capable of shutting off the power to the holiday detector 1. The holiday detector 1 can only be turned on if the power button 4 is depressed while the safety button 3 is engaged. In addition, the holiday detector 1 only remains on if the safety button 3 remains engaged.

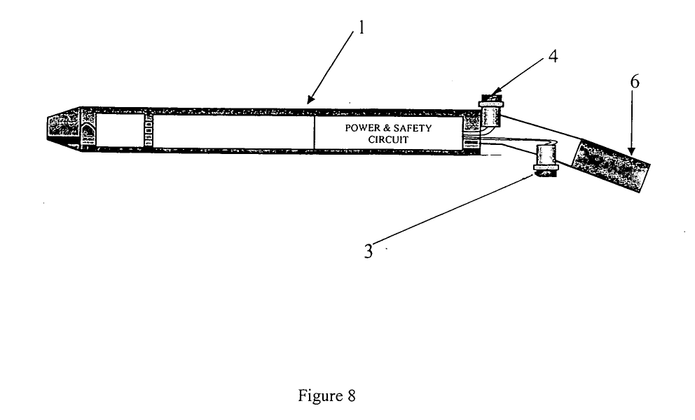

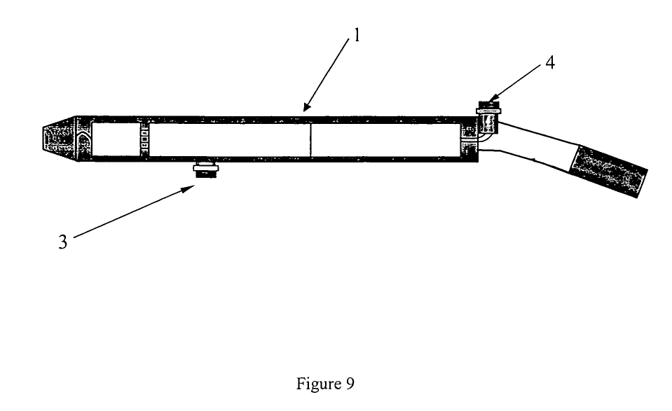

FIG. 8 shows another preferred embodiment of the present invention without an appendage 2. In this embodiment, the user directly engages the safety button 3 when properly holding the holiday detector 1. Although FIG. 8 displays the safety button 3 on the bottom part of the handle 6, other preferred embodiments have the safety button 3 located on other areas of the handle 6, including on the side or top of the handle 6. In addition, as shown in FIG. 9, the safety button 3 can be located towards the front of the holiday detector itself where the user's other hand typically holds the holiday detector 1 while operating it. Although FIG. 9 displays the safety button 3 on the bottom part of the holiday detector, other preferred embodiments have the safety button 3 located on other areas of the holiday detector where users typically hold it; towards the front portion of the holiday detector

In sum, these preferred embodiments are comprised of a holiday detector 1, a power button 4, and a safety button 3 capable of shutting off the power to the holiday detector 1. The holiday detector 1 can only be turned on if the power button 4 is depressed while the safety button 3 is engaged. In addition, the holiday detector 1 only remains on if the safety button 3 remains engaged.

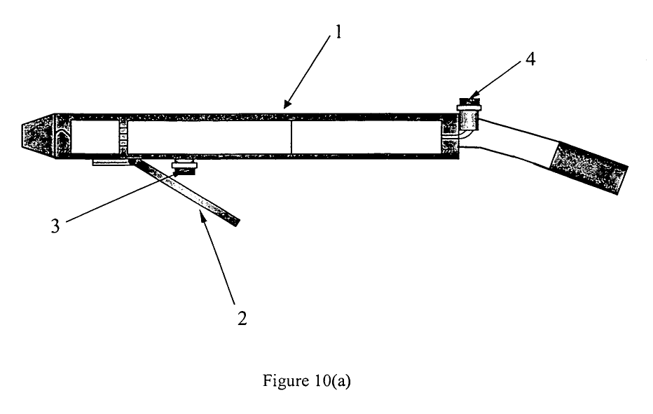

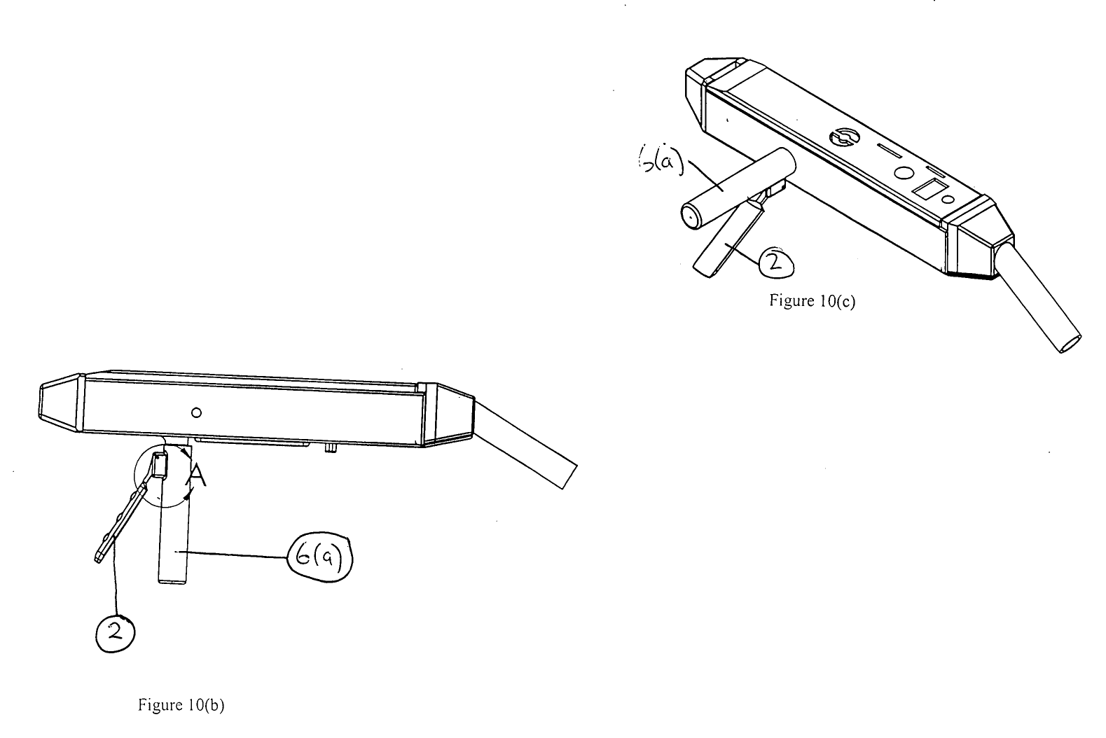

Analogously, in other preferred embodiments in which an appendage 2 utilized, the appendage 2 can be located on the side or top of the handle 6 of the holiday detector 1 along with the safety button 3. The appendage 2 could also be located towards the front of the holiday detector 1 in conjunction with the safety button 3, as seen in FIG. 10(a).

FIGS. 10(b) and 10(c) illustrate another preferred embodiment of the present invention where an appendage (2) engages a safety switch on a forward handle 6(a). The forward handle 6(a) can be coupled to the bottom or side of the holiday detector 1. Another preferred embodiment of the present invention without the appendage, has the user engage a safety button coupled to the forward handle 6(a).

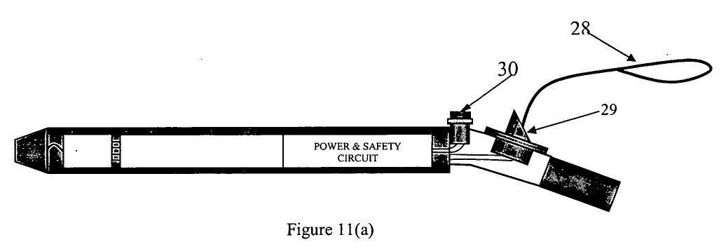

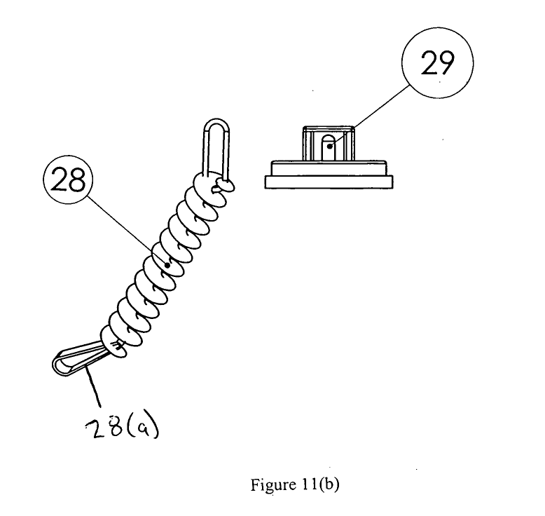

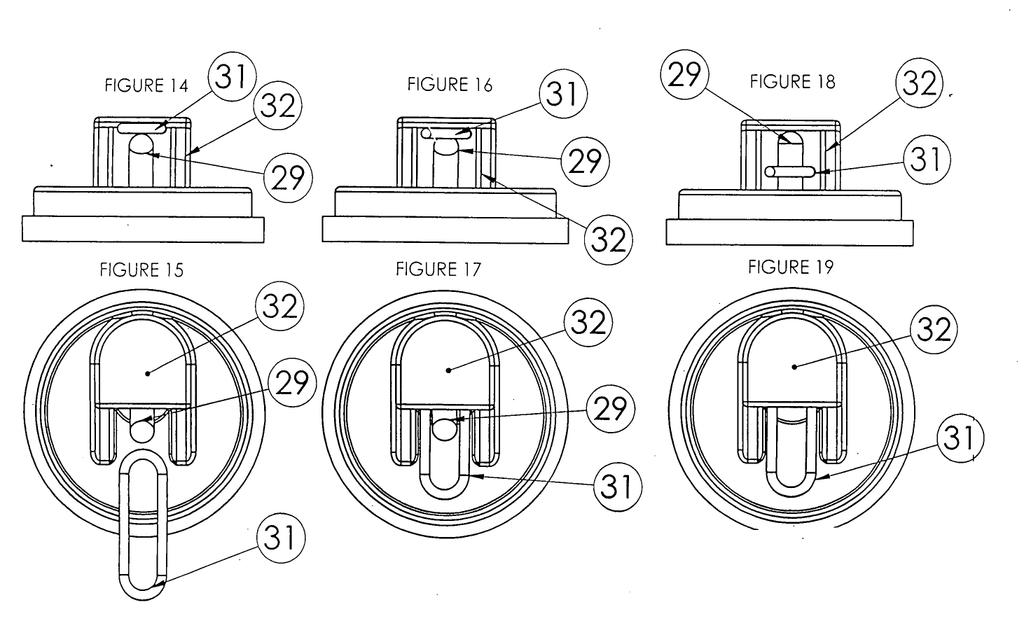

FIGS. 11-20 demonstrate another preferred embodiment of the present invention. In this embodiment, a lanyard 28 which is attached to the user at one end and the safety switch 29 at the other, automatically shuts off the power to the holiday detector 1 when the holiday detector 1 is separated from the user. As the holiday detector 1 separates from the user, the lanyard 28 becomes taut, engaging and thus switching the safety switch 29 shutting off the power to the holiday detector 1.

FIG. 11(b) displays a lanyard 28 which connects on one end to a user with any attachment means commonly known, such as a clip 28(a). The clip can be attached to an article of clothing. Another embodiment utilizes a loop which can secure around the user's wrist. The other end of the lanyard connects to the safety switch 29.

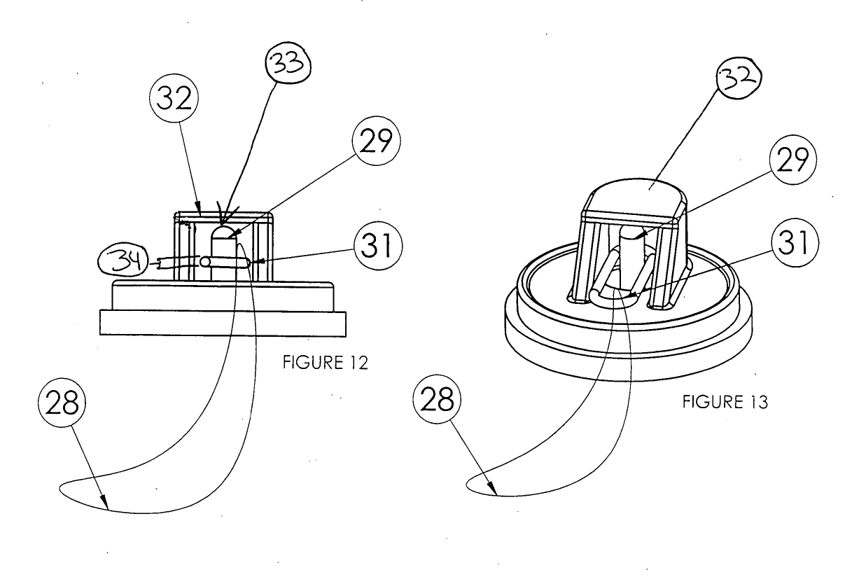

FIGS. 12-19 illustrate the interaction between the lanyard 28 and the safety switch 29. FIGS. 12 and 13 depict a lanyard 28 attached to a lanyard connector 31, while the lanyard connector 31 is on the safety switch 29. The safety switch 29 is partially enclosed by a switch cover 32. When the safety switch 29 is activated, the gap 33 between the safety switch 29 and the switch cover 32 is less than the width 34 of the lanyard connector 31. This ensures that the lanyard connector 31 stays engaged with the safety switch 29 and does not detach without switching the safety switch 29.

FIGS. 14 through 17 demonstrate the placement of the lanyard connector 31 on the safety switch 29. Once the lanyard connector 31 is placed on the safety switch 29 the safety switch 29 can be activated as seen in FIGS. 18 and 19. Once activated the safety switch 29 can only be switched when the lanyard 28 pulls the lanyard connector 31.

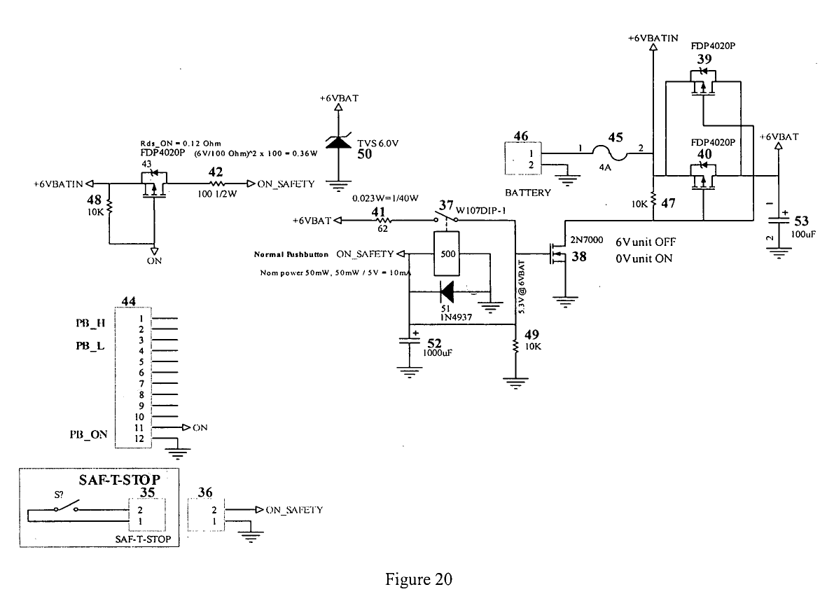

FIG. 20 shows the power & safety circuit diagram for the present embodiment. In FIG. 20, JP5 connector 35 is attached to a jumper cable that is connected to the safety switch 29. The other side of JP5 connector 35 plugs into the JP4 jumper cable 36. The lanyard 28 is attached on one side to the user with any attachment means commonly used, such as a clip. The other side of the lanyard 28 attaches to the safety switch 29. When the safety switch 29 is open a short circuit pass between pins 1 and 2 of JP4 jumper cable 36 is broken. At this point the holiday detector 1 is in able to power up. Once the power button is pressed the unit will be powered. K6 relay 37 is wired in a self-latching configuration. Once the battery voltage is applied to the ON_SAFETY side of K6 coil, K6 relay 37 will stay engaged even after the power coming from Q21 MOSFET 43 is removed. As can be seen from FIG. 20, the 6V battery voltage is routed through pins 7 and 1 back to pin 2 of the relay's coil which allows the relay to stay powered permanently. Output of the relay is connected to the Q17 inverter 38. Since Q18 transistor 39 and Q19 transistor 40 are P-Channel MOSFETs, they will require a negative voltage between gate and source to turn on, or V_{G}<V_{S}−V_{TH}, where V_{TH} is the threshold voltage of FDP4020 MOSFET. When K6 relay 37 is engaged Q17 inverter 38 is turned on by the positive voltage coming from +6VBATIN through R56 resistor 41. In turn, Q17 inverter 38 pulls both gates of Q18 transistor 39 and Q19 transistor 40 to a low potential well below V_{TH} placing both MOSFETs in the saturation, or switch, region. As a result current starts flowing through Q18 transistor 39 and Q19 transistor 40 and the holiday detector 1 gets power.

In the circuit R59 resistor 42 is the current limiting resistor used to prevent an over-current condition when Q21 transistor 43 is active and conducting current. The gate of Q21 transistor 43 is connected to the power button 30 through JP2 jumper cable 44. When the power button 30 is pressed in, the gate of Q21 transistor 43 is pulled to a low potential and Q21 transistor 43 gets activated providing power for the K6 self-latching relay 37.

A 4A fuse 45 connected to the battery connector 46 protects the circuitry from overload currents. R60 resistor 47 and R69 resistor 48 are pull-up resistors. R61 resistor 49 is a pull down resistor to keep Q17 transistor 38 off when no voltage is applied to the gate of the transistor. D27 transient voltage suppressor 50 protects Q17 transistor 38, Q18 transistor 39, and Q19 transistor 40 from transient high voltage spikes. D17 Diode 51 is a kickback voltage protection diode. C31 Capacitor 52 is used to filter out noise spikes that could fault-trigger K6 relay 37. C33 capacitor 53 is an output voltage filtering capacitor.

Should the holiday detector 1 separate from the user, the lanyard 28 will switch the safety switch 29 and the short circuit between pins 1 and 2 of JP4 jumper cable 36 will be complete. Since pin 2 of JP4 jumper cable 36 is connected to one side of K6 coil 37 (in FIG. 2 shown as ON_SAFETY connection node) and pin 1 of JP4 jumper cable 36 is connected to the ground, both sides of K6 relay 37 are shorted down to ground. While both sides of K6 coil are connected to ground the coil has no power and K6 relay 37 stays open. The relay will not engage even if power is applied to the coil through Q21 transistor 43 and R59 resistor 42. As a result the unit will stay powered down even if user engages the power button 30.

In sum, this preferred embodiment is comprised of a holiday detector 1, a power button 30, a safety switch 28 capable of shutting off the power to the holiday detector 1, and a lanyard 28 coupled to the safety switch 28.

Although the present invention has been described in detail with respect to certain preferred versions thereof, other versions are possible. Therefore, the scope of the claims should not be limited to the description of the preferred versions contained herein.

1. An apparatus comprised of:
(a) a holiday detector;
(b) a power button; and
(c) a safety button capable of shutting off the power to said holiday detector.

2. The apparatus of claim 2 wherein the holiday detector can only be turned on if the power button is depressed while the safety button is engaged.

3. The apparatus of claim 1 wherein the holiday detector only remains on if the safety button remains engaged.

4. An apparatus comprised of:
(a) a holiday detector;
(b) a power button;
(c) an appendage coupled to the holiday detector;
(d) a safety button capable of being engaged by an appendage;
(d) said safety button capable of shutting off the power to said holiday detector.

5. The apparatus of claim 4 wherein the holiday detector can only be turned on if the power button is depressed while the safety button is engaged.

6. The apparatus of claim 4 wherein the holiday detector only remains on if the safety button remains engaged.

7. An apparatus comprised of:
(a) a holiday detector;
(b) a power button;
(c) a safety switch capable of shutting off the power to said holiday detector; and
(d) a lanyard coupled to the safety switch.
